(19) United States
(12) Patent Application Publication
(10) Pub. No.: US 2013/0122629 A1
(43) Pub. Date: May 16, 2013

(54) SYSTEMS, METHODS AND PRODUCTS INCLUDING FEATURES OF LASER IRRADIATION AND/OR CLEAVING OF SILICON WITH OTHER SUBSTRATES OR LAYERS

(71) Applicant: Venkatraman Prabhakar, Pleasanton, CA (US)

(72) Inventor: Venkatraman Prabhakar, Pleasanton, CA (US)

(21) Appl. No.: 13/572,258

(22) Filed: Aug. 10, 2012

Related U.S. Application Data
(63) Continuation of application No. 12/954,837, filed on Nov. 26, 2010, now abandoned.
(60) Provisional application No. 61/264,614, filed on Nov. 25, 2009.

(51) Int. Cl. H01L 31/18; H01L 21/78

(52) U.S. Cl. CPC H01L 31/18; H01L 21/78
USPC 438/57; 438/458

(57) ABSTRACT

The present innovations relate to optical/electronic structures, and, more particularly, to methods and products consistent with composite structures for optical/electronic applications, such as solar cells and displays, composed of a silicon-containing material bonded to a substrate and including laser treatment.

CROSS-REFERENCE TO RELATED APPLICATION(S)

This is a continuation of application Ser. No. 12/954,837, filed Nov. 26, 2010, published as U.S. 2011/0165721 A1, and claims benefit and priority of U.S. provisional patent application No. 61/264,614, filed Nov. 25, 2009, all of which are incorporated herein by reference in entirety.

### BACKGROUND

1. Field

The present innovations relate to optical/electronic structures, and, more particularly, to methods and products consistent with composite structures for optical/electronic applications, such as solar cells and displays, composed of a silicon-containing material bonded to a substrate.

2. Description of Related Information

Existing literature discusses producing thin layers of semiconductor material by implanting ions into the base material up to a specified junction, followed by thermal treatment and application of force to separate the thin layer along the junction. Such methods typically involve implantation of light ions such as H and He into silicon at the desired depth. After that, a thermal treatment is performed to stabilize the microcavities. In existing systems, this thermal treatment step is performed at equal to or greater than 550° C., a temperature too high to reliably perform on glass substrates. For many applications, such as solar, use of cheaper glass such as borosilicate/borofloat and soda-lime glass is essential. Therefore, use of glass substrates that withstand higher temperatures such as the Corning “Eagle” glass is not practical. While some lower temperature thermal treatments exist, they are unable to reliably separate thin layers on glass. The conventional treatments also require an atomically smooth glass with an RMS roughness of <5 Å. Although smooth glasses such as display industry glasses similar to the Corning “Eagle” are available, the cheaper glasses such as borofloat and soda-lime glass have a much rougher surface. If conventional techniques were attempted on cheaper glass, delamination would occur at another weak interface, such as the interface between the nitride and the silicon layer, instead of at the damaged microcavities.

As set forth below, one or more exemplary aspects of the present inventions may overcome such drawbacks and/or otherwise impart innovative aspects, such as the use of soda-lime or borosilicate/borofloat glass since they do not require furnace anneals at higher than 400C and can tolerate a rougher glass surface.

### SUMMARY

Systems, methods, devices, and products of processes consistent with the innovations herein relate to composite structures composed of a silicon-containing material bonded to a substrate.

It is to be understood that both the foregoing general description and the following detailed description are exemplary and explanatory only and are not restrictive of the invention, as described. Further features and/or variations may be provided in addition to those set forth herein. For example, the present invention may be directed to various combinations and subcombinations of the disclosed features and/or combinations and subcombinations of several further features disclosed below in the detailed description.

### DESCRIPTION OF THE DRAWINGS

The accompanying drawings, which constitute a part of this specification, illustrate various implementations and aspects of the present invention and, together with the description, explain the principles of the invention. In the drawings:

FIG. 1 illustrates an exemplary structure including a silicon-containing piece and a substrate, showing laser irradiation from the bottom, consistent with aspects related to the innovations herein.

FIG. 2 illustrates an exemplary structure showing a cleaving aspect, consistent with one or more aspects related to the innovations herein.

FIG. 3 illustrates an exemplary structure including a silicon-containing piece and a substrate, showing laser irradiation from the top, consistent with aspects related to the innovations herein.

FIG. 4 illustrates an exemplary method of producing a structure, including implantation and laser treatment, consistent with aspects related to the innovations herein.

FIG. 5 illustrates another exemplary method of producing a structure, including implantation and laser treatment, consistent with aspects related to the innovations herein.

FIG. 6 illustrates still another exemplary method of producing a structure, including implantation and laser treatment, consistent with aspects related to the innovations herein.

FIG. 7 illustrates yet another exemplary method of producing a structure, including implantation and laser treatment, consistent with aspects related to the innovations herein.

FIG. 8 illustrates still a further exemplary method of producing a structure, including implantation and laser treatment, consistent with aspects related to the innovations herein.

FIG. 9A-9B illustrates still further exemplary aspects of producing a structure, including laser treatment, consistent with aspects related to the innovations herein.

FIGS. 10A-10B illustrate exemplary innovations regarding laser treatment of the silicon-containing material, consistent with aspects related to the innovations herein.

FIGS. 11A-11B illustrate further exemplary innovations regarding laser treatment of the silicon-containing material, consistent with aspects related to the innovations herein.

### DETAILED DESCRIPTION OF EXEMPLARY IMPLEMENTATIONS

Reference will now be made in detail to the invention, examples of which are illustrated in the accompanying drawings. The implementations set forth in the following description do not represent all implementations consistent with the claimed invention. Instead, they are merely some examples consistent with certain aspects related to the invention. Wherever possible, the same reference numbers will be used throughout the drawings to refer to the same or like parts.

Systems, methods, devices, and products of processes consistent with the innovations herein relate to composite structures composed of a silicon-containing material bonded to a substrate. Consistent with the disclosure, aspects of the innovations herein may include one or more of the following and/or other variations and laser treatment set forth below: (1) use of laser scanned across a silicon-containing material bonded to glass to help the cleaving of silicon on glass to desired thickness; (2) use of laser anneal to strengthen the bond between the silicon and the substrate; (3) use of laser anneal to weaken the damaged layer created by the light ion implantation; and/or (4) application of one or more lasers either through the substrate, or through the silicon material, or both.

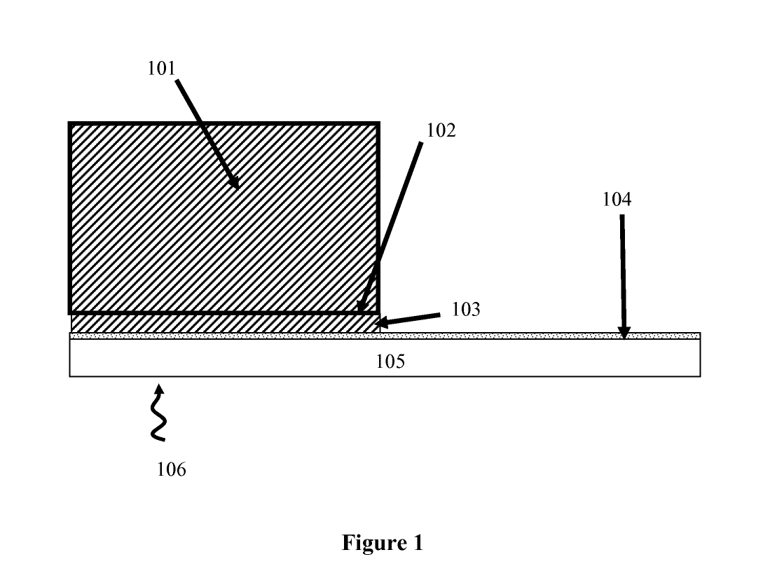

FIG. 1 is a cross-section of an illustrative implementation consistent with one or more aspects of the innovations herein. As shown by way of example in FIG. 1, substrate 105, such as glass, may be coated with a layer 104. Additionally, a silicon-containing material 101, such as a silicon wafer or piece, may be bonded on the substrate 105. Such silicon material 101 may have a portion 103 which has been implanted with a light ion, e.g. H or He, or a combination of light ions before the bonding. The depth at which the ions are implanted is shown as a damaged region 102 in FIG. 1.

As shown in FIG. 1, a laser 106 which can be absorbed by the silicon is scanned across the area of the silicon-containing material 103. Here, the laser may be applied consistent with innovations herein to create thermal mismatch or stress at the damaged region 102. Further, the laser wavelength in some implementations may be chosen so that the substrate 105 is transparent to the laser. In some exemplary implementations, the wavelength of the laser can be in the range of about 350 nm to about 1070 nm, or about 350 nm to about 850 nm, in narrower ranges, such as about 500 nm to about 600 nm, and/or at specific wavelengths. For example, in some implementations, laser irradiation may be applied at a wavelength of 515 nm or of 532 nm. In one exemplary implementation, the layer 104 may be a silicon nitride (SiN) layer deposited by PECVD (plasma enhanced chemical vapor deposition). Further, some implementations may include SiN layers having a refractive index of about 1.7 to about 2.2. In one exemplary implementation, this SiN layer has a refractive index of about 2.0, and therefore it acts as an anti-reflective coating in between the silicon and glass layers. In some implementations, the SiN layer could be modified with oxygen to form SiON (silicon oxynitride) and/or there could be a thin layer (e.g., about 5 to about 30 nm; and, in some exemplary implementations, about 10 nm) of SiON or SiO2 deposited on top of the SiN layer to achieve better passivation and stress relief.

In still further embodiments, additional layers may be deposited on top of the SiN/SiO₂ layers before the bonding step, as needed, e.g., for specific applications, etc. For example, an amorphous silicon layer may be deposited over the SiN/SiO₂ layer in certain instances. In some exemplary implementations, the glass can be any variety of glass that is transparent to the chosen wavelength ranging in size from about 200 mm×200 mm to a Gen 10 glass that is about 3 m×3 m. In one exemplary implementation, the glass may be a Gen 5 glass (1.1 m×1.3 m). As to the type of glass used, the innovations herein are particularly well suited to solar cell fabrication using soda-lime glass or borosilicate/borofloat glass.

In accordance with the above and/or additional aspects of laser irradiation, anneal or other aspects set forth elsewhere herein, innovative systems, methods and products by processes may be achieved. For example, according to certain aspects of innovations herein, only thermal treatments at temperatures at or below 500° C. are needed performed, enabling use of standard glass materials. Further, aspects of the innovations herein may utilize sufficient temperatures during the anneal process, such that duration of the anneal is short enough that cost of manufacture is not unacceptably increased. Innovations herein also overcome technical problems associated with lower temperature anneal, including insufficient bond strength that leads to cleaving at the nitride interface (i.e. between layers 103 and 104, FIG. 1), rather than at the damaged layer 102. Aspects of systems and methods consistent with the innovations herein may involve laser treatment with or without a low temperature (<500° C.) thermal treatment. In some exemplary implementations, the laser treatment may strengthen the semiconductor material bonding to the substrate, such as glass, and may weaken the damaged layer created by the implantation. As such, cleaving of the semiconductor material may be provided. Further, some implementations of the innovations herein do not involve anneals with temperature greater than 500° C. and are therefore compatible with low temperature substrates such as glass and plastic. Moreover, laser treatments consistent with the innovations herein may be a few minutes long, compared to the high temperature anneal which takes hours to complete.

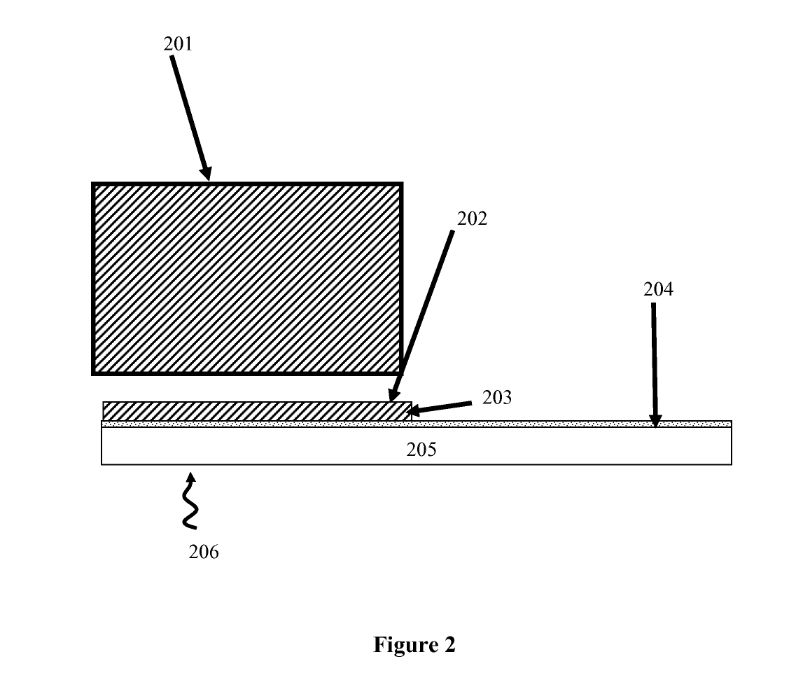

FIG. 2 illustrates an exemplary structure showing a cleaving aspect, consistent with one or more aspects related to the innovations herein. The system of FIG. 2 is similar to that of FIG. 1, including the substrate 205, layer 204, silicon-containing material 201, 203, and laser 206. The implementation illustrated in FIG. 2 further shows the silicon-containing material cleaved into two portions, a first portion 201 that is removed, and a second portion 203 that remains on the substrate.

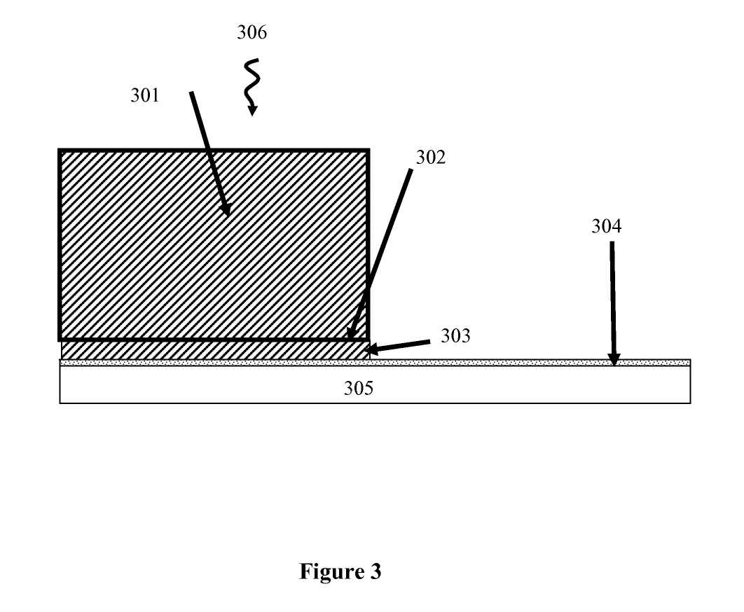

FIG. 3 illustrates an exemplary structure including a silicon-containing piece and a substrate, showing laser irradiation from the bottom, consistent with aspects related to the innovations herein. The system of FIG. 3 is similar to that of FIGS. 1 and 2, including the substrate 305, layer 304, silicon-containing material 301, 303, and laser 306. The implementation shown in FIG. 3 illustrates the laser 306 being applied from the top, through the silicon-containing material 301/303.

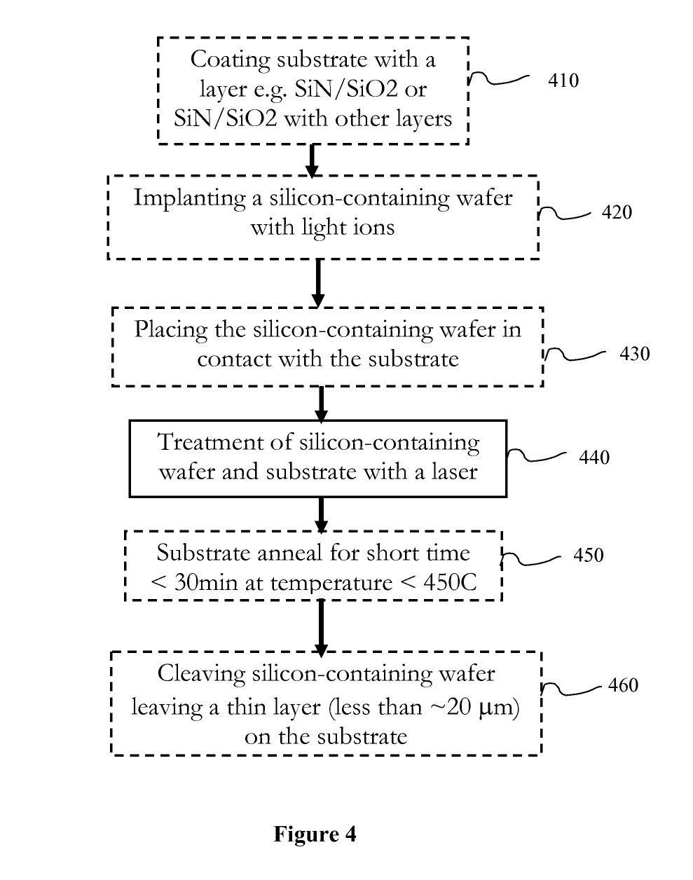

FIG. 4 illustrates an exemplary method of producing a composite substrate consistent with aspects of the innovations herein. As shown in FIG. 4, an optional step of coating the substrate with a layer 410, e.g. SiN/SiO2, SiN/SiO2 and additional layers, SiN/SiO2/amorphous silicon, or other layers such as anti-reflective layers, etc., may initially be performed. In general, however, a step of implanting the silicon-containing material with light ions 420 is first performed, i.e., to a specified depth at which the material is to be cleaved. In certain implementations, where the cleaving of the material is not desired, the implantation step can be skipped and entire thickness of the silicon-containing material may be left on the substrate without cleaving after the laser irradiation/treatment. Next, the silicon-containing material is brought into contact with the substrate 430. Then, a step of treating/irradiating the silicon-containing material and the substrate with a laser 430 is performed, consistent with the innovations set forth elsewhere herein.

Further, in some optional, exemplary implementations, an overall substrate anneal step (e.g., furnace anneal, rapid thermal anneal [RTA], etc.) of shorter duration 450 may then be performed, such as less than 30 minutes, and within certain temperature ranges, such as below about 450° C. And, in further optional and exemplary implementations, a final step of cleaving the silicon-containing material may be performed 460, e.g., to leave a thin layer of the silicon-containing material on the substrate. Here, for example, layers of less than about 20 microns may be left on the substrate, such as layers in the range of about 0.1 to about 12 microns, or about 0.25 to about 1 micron, or about 0.5 micron.

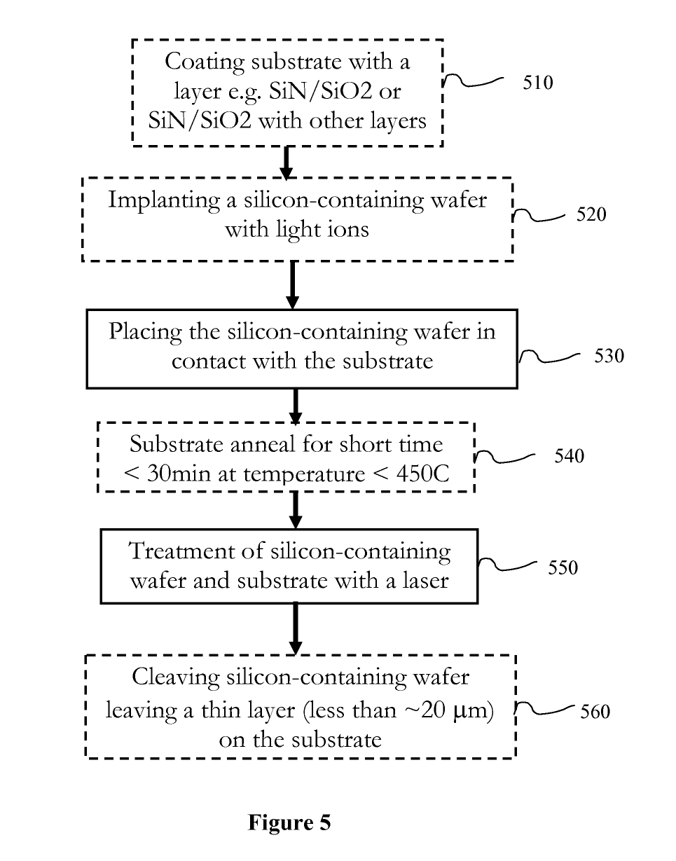

FIG. 5 illustrates another exemplary method of producing a structure, consistent with aspects related to the innovations herein. The implementation of FIG. 5 is similar to that of FIG. 4, including steps of coating 510, implanting 520, placing the material into contact with the substrate 530, annealing 540, laser treatment/irradiation 550, and cleaving 560. However, in the implementation illustrated in FIG. 5, the substrate anneal (e.g., furnace, RTA, etc.) is performed prior to the laser irradiation. The substrate anneal heats the entire substrate up to the specified temperature in contrast to a laser irradiation, which only heats up the silicon-containing material and the layer(s) 510, while leaving the substrate without a significant temperature rise. The laser chosen for treatment in exemplary implementations has a wavelength between about 350 nm and about 1070 nm, such as wavelengths between 350 nm and 700 nm, or about 515 nm or about 532 nm. The cleaving of the silicon-containing wafer is done at about the range (Rp) of the light ion implantation. However, due to the statistical nature (straggle) of the implantation, this cleave plane is not perfectly precise and leads to a somewhat rough surface after cleaving.

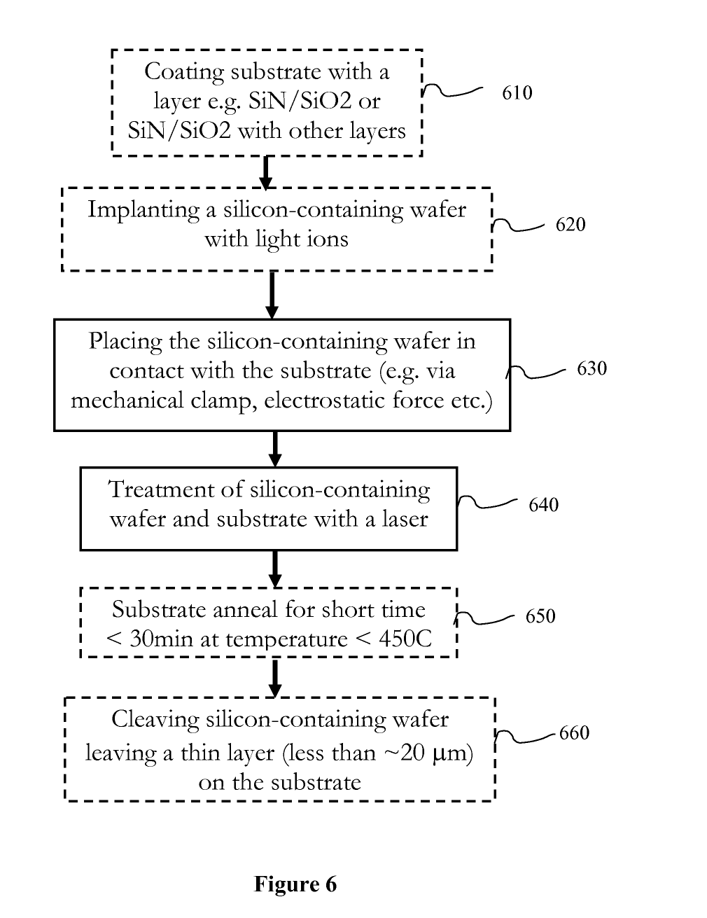

FIG. 6 illustrates another exemplary method of producing a structure, consistent with aspects related to the innovations herein. The implementation of FIG. 6 is similar to that of FIG. 4, including steps of coating 610, implanting 620, placing the material into contact with the substrate 630, laser treatment/irradiation 640, annealing 650 and cleaving 660. In the implementation illustrated in FIG. 6, the silicon-containing layer or wafer is placed in contact with the substrate using mechanical clamps, vacuum or electrostatic forces . In some implementations, pressure may applied to the silicon-containing layer to achieve good contact between the layer and the substrate. In exemplary implementations, the substrate may be glass such as borosilicate/borofloat glass or soda-lime glass. In other implementations, the substrate may be metallic such as steel or aluminum sheets or foils.

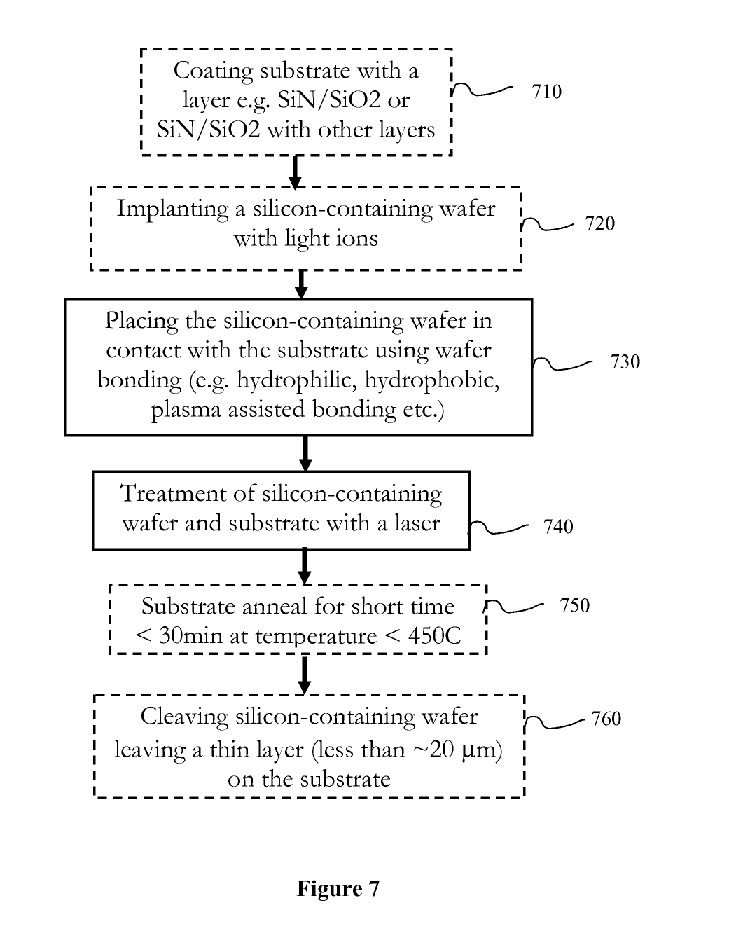

FIG. 7 illustrates another exemplary method of producing a structure, consistent with aspects related to the innovations herein. The implementation of FIG. 7 is similar to that of FIG. 6, including steps of coating 710, implanting 720, placing the material into contact with the substrate 730, laser treatment/irradiation 740, annealing 750 and cleaving 760. In the implementation illustrated in FIG. 7, the silicon-containing layer or wafer is placed in contact with the substrate using wafer bonding such as hydrophilic, hydrophobic or plasma assisted bonding. In these implementations as well, the substrate anneal (furnace or RTA) may be performed before or after the laser irradiation/treatment.

In alternative implementations of the innovation herein, further low temperature anneals may be performed before or after the laser anneal to assist with the cleaving process. In some implementations, such anneal can be between about 200° C. to about 450° C., in ranges of time spanning from 5 minutes to about 30 minutes. In one exemplary implementation, an anneal is done at 300° C. for 15 minutes prior to the laser treatment.

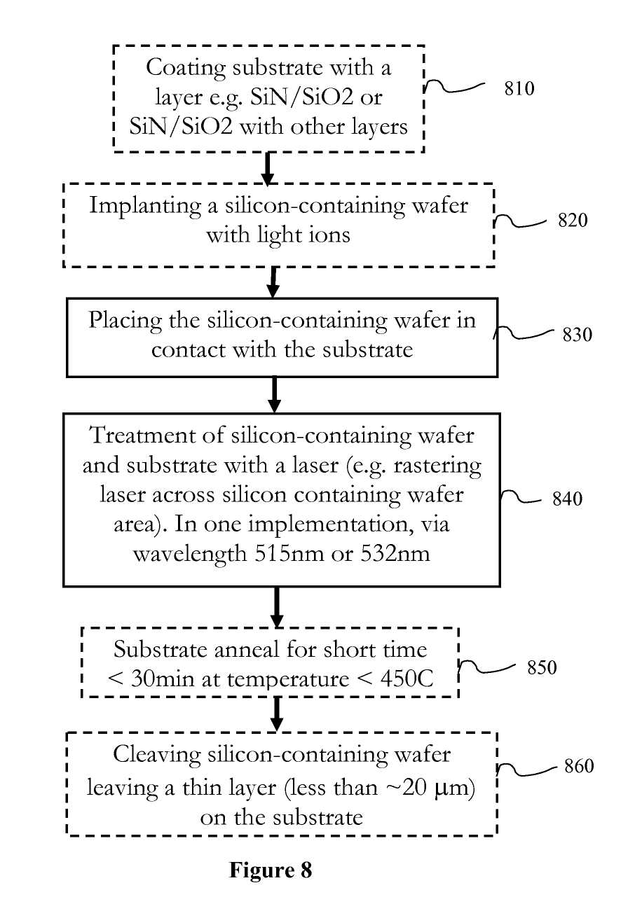

FIG. 8 illustrates another exemplary method of producing a structure, consistent with aspects related to the innovations herein. The implementation of FIG. 8 is similar to that of FIG. 7, including steps of coating 810, implanting 820, placing the material into contact with the substrate 830, laser treatment/irradiation 840, annealing 850 and cleaving 860. In the implementation illustrated in FIG. 8, the step of laser irradiation may include treatment (e.g., rastering, line source, etc.) of the silicon-containing material and substrate with a laser having a wavelength of 515 nm or with a laser having a wavelength of 532 nm, which, by virtue of the specific applications and parameters set forth herein, impart distinctive improvements in weakening the damaged layer created by the light ion implantation (yielding beneficial cleaving characteristics) while also strengthening the bond between the silicon-containing material and the substrate.

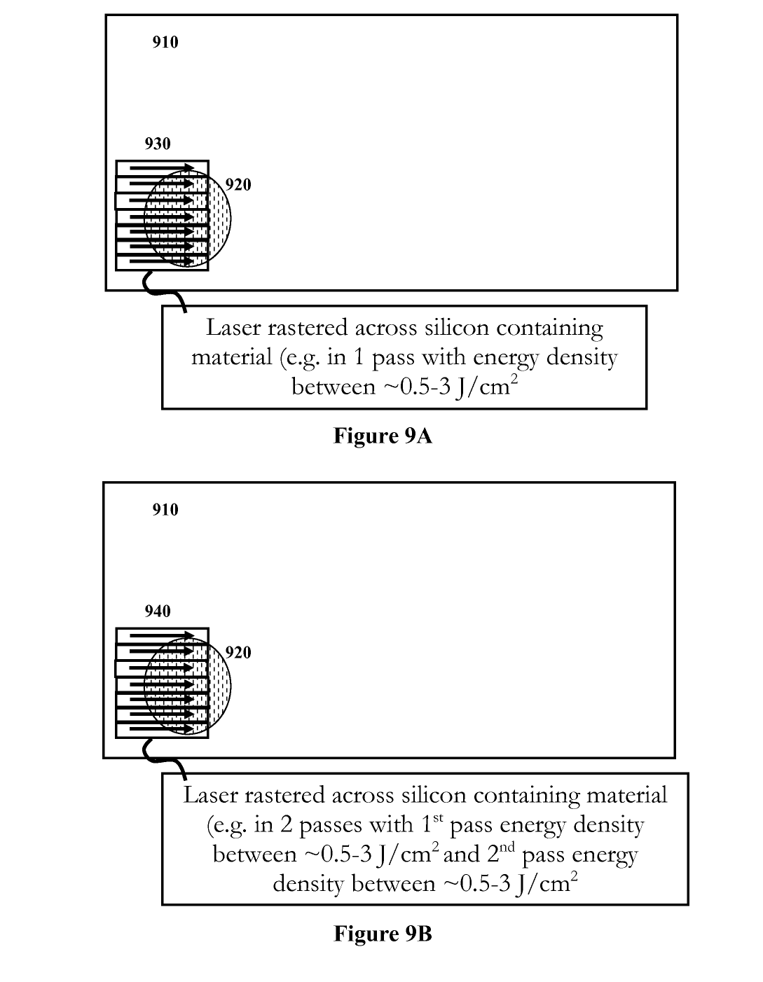

FIG. 9A-9B illustrates still a further exemplary aspects of producing a structure, including laser treatment, consistent with aspects related to the innovations herein. Referring to FIG. 9A, an exemplary laser irradiation/treatment process is shown, comprised of a single pass of the laser over each region at an energy density of between about 0.5 and about 3 J/cm2. The energy density is calculated by dividing the laser pulse energy by the area of the spot. This depends on laser power, laser repetition rate, scan speed and the focusing optics used. Indeed, the laser may be focussed as a line source rather than as a spot. However, the energy density calculations are similar i.e., dividing the laser pulse energy by the area of the line in case of a line source. In exemplary implementations, there may be significant overlap of neighboring spots/lines as the laser is rastered across the silicon-containing material. In some implementations, the laser rastering may start on the substrate outside the area of the silicon-containing material and then move on to the silicon-containing material. In other implementations, the rastering may not cover the complete area of the silicon-containing material. In addition, multiple passes of the laser may also be performed. For example, as shown in FIG. 9B, an exemplary rastering process including 2 passes of the subject laser is shown. FIG. 9B illustrates an exemplary implementation wherein the laser irradiation/treatment comprises a first pass of the laser at an energy density of between about 0.5 and about 3 J/cm2, and a second pass of the laser at an energy density of between about 0.5 and about 3 J/cm2. Further, in such implementations, the laser may be passed over each region at an energy density of about 2 J/cm², e.g., for lasers of 515 nm or 532 nm, and especially for absorptions depths of less than a micron. Additionally, in multi-pass implementations, energy density may also be increased or decreased as between the differing passes. Indeed, results of improved bonding or better cleaving have been unexpectedly achieved as a function of varying the energy densities in this manner. Furthermore, other parameters of the laser application may also be varied, such as the speed at which the laser is passed of the structure. For example, the laser may be passed over the substrate at slower speeds, such as between about 0.0001 to about 0.01 cm²/sec, and/or at higher speeds, such as between about 0.01 to about 10 cm²/sec. In one exemplary implementation, here, a step of laser irradiation/treatment may comprise a first pass of the laser, at a speed/rate of about 0.0001 to about 0.01 cm²/sec, at an energy density of between about 0.5 and about 1 J/cm2, and a second pass of the laser, at a speed/rate of about 0.01 to about 10 cm²/sec at an energy of between about 1 and about 3 J/cm2.

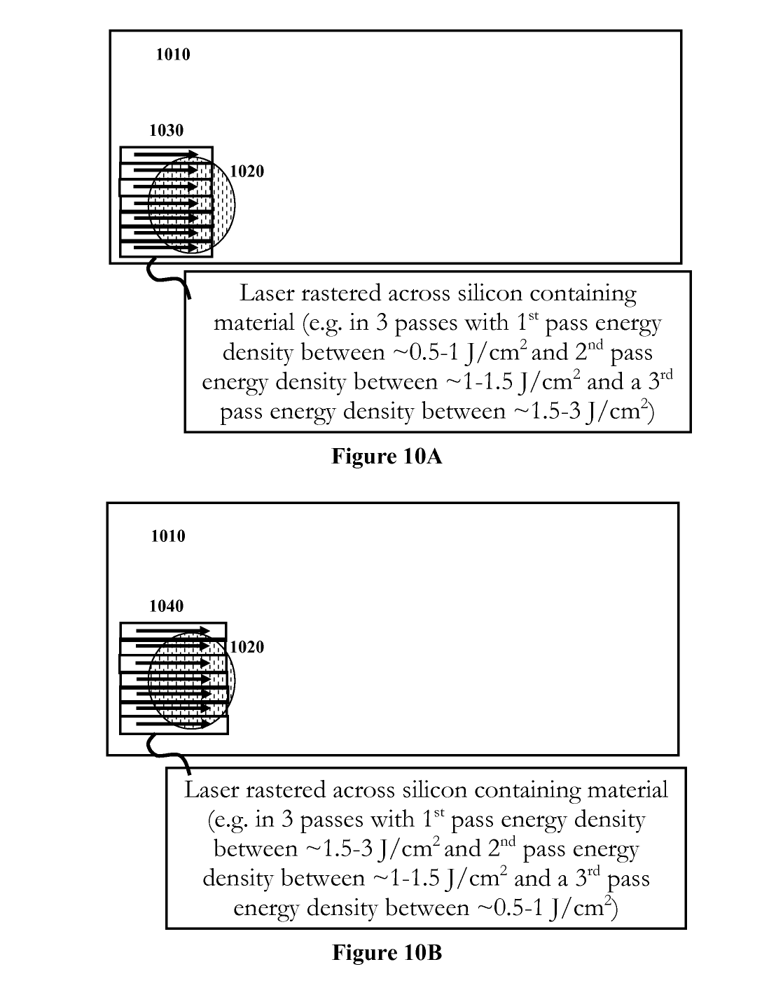

FIGS. 10A-10B illustrate exemplary innovations regarding laser treatment of the silicon-containing material including 3 passes of a laser, consistent with aspects related to the innovations herein. Referring to FIGS. 10A-10B, exemplary laser irradiation/treatment processes are shown, comprised of 3 passes of a laser or different lasers over each region at an energy density of between about 0.5 and about 3 J/cm2. For example, FIG. 10A illustrates an exemplary implementation wherein the laser irradiation/treatment comprises a first pass of the laser at an energy density of between about 0.5 and about 1 J/cm2, a second pass of the laser at an energy density of between about 1 and about 1.5 J/cm2, an a third pass of the laser at an energy density of between about 1.5 and about 3 J/cm2. Further, FIG. 10B illustrates another exemplary implementation wherein the laser irradiation/treatment comprises a first pass of the laser at an energy density of between about 1.5 and about 3 J/cm2, a second pass of the laser at an energy density of between about 1 and about 1.5 J/cm², an a third pass of the laser at an energy density of between about 0.5 and about 1 J/cm².

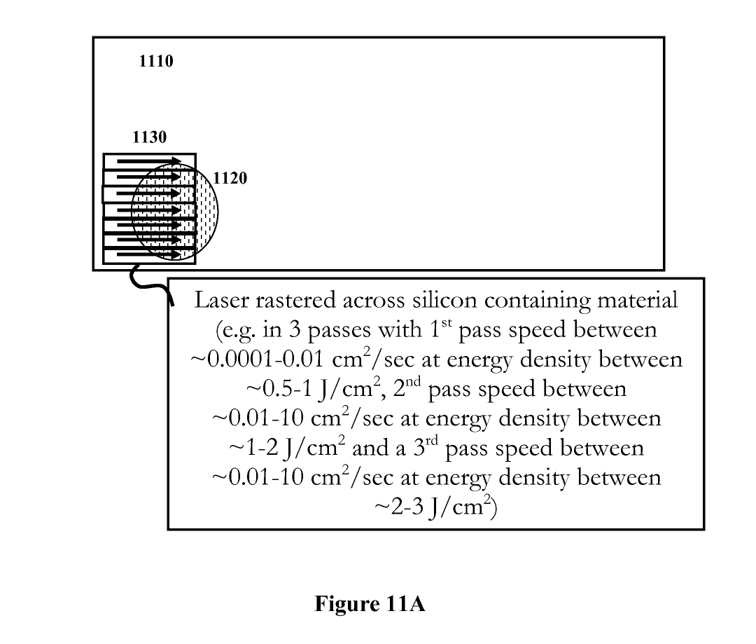

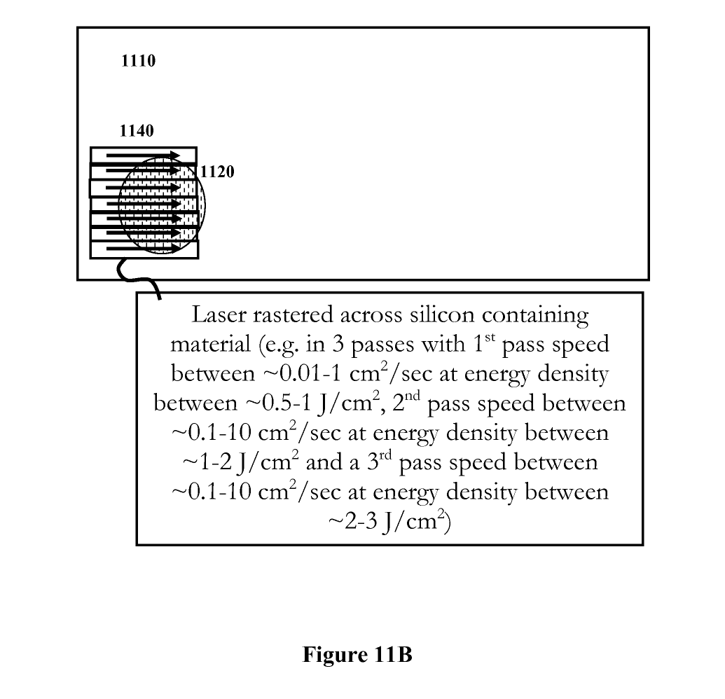

FIGS. 11A-11B illustrate further exemplary innovations regarding laser treatment of the silicon-containing material, consistent with aspects related to the innovations herein. Referring to FIGS. 11A-11B, exemplary laser irradiation/treatment processes are shown, comprised of 3 passes of a laser or different lasers over each region at different speeds and/or energy densities. For example, FIG. 11A illustrates an exemplary implementation wherein the laser irradiation/treatment comprises a first pass of the laser, at a speed/rate of about 0.0001 to about 0.01 cm²/sec, at an energy density of between about 0.5 and about 1 J/cm2, a second pass of the laser, at a speed/rate of about 0.01 to about 10 cm²/sec at an energy of between about 1 and about 2 J/cm2, and a third pass of the laser, at a speed/rate of about 0.01 to about 10 cm²/sec at an energy of between about 2 and about 3 J/cm2. Further, FIG. 11B illustrates another exemplary implementation, wherein the laser irradiation/treatment comprises a first pass of the laser, at a speed/rate of about 0.01 to about 1 cm2/sec at an energy density of about 0.5 to about 1 J/cm², second pass of a laser at a speed/rate of about 0.1 to about 10 cm2/sec at an energy density of about 1 to about 2 J/cm², and a third pass of a laser at a speed/rate of about 0.1 to about 10 cm2/sec at an energy density of about 2 to about 3 J/cm².

In accordance with innovations herein, then, temporal requirements for the bonding and cleaving of the silicon wafer on glass may be reduced from 3-4 hours at 550° C. to less than 45 minutes. This may reduce the cycle time of the process as well as the cost. As such, systems and methods herein may be used to realize lower cost semiconductors and solar cells. Innovative systems and methods may also be applied to save cost and cycle time in preparing silicon-on-glass substrates for the production of flat panel displays.

In the case of solar cells, this also enables a continuous production line, as most other steps are less than 10 minutes long. Accordingly, features imparting such improved processing times are especially innovative as drawbacks of having time-consuming processing steps (4 hours, etc.) include the need for large amounts of inventory and storage, especially before and after lengthy anneal steps. These drawbacks significantly increase the cost and complexity of a solar cell manufacturing line. On the other hand, the innovations herein entail only about 15 minutes and hence perfectly integrate with a continuous, low-cost solar cell production lines.

Turning to some specific applications, namely solar cell applications, use of the innovations herein with a SiGe (silicon-germanium) wafer, piece or layer, rather than pure silicon material, increases the light absorption in the infrared region, thereby increasing the efficiency of solar cells. In one exemplary implementation, a silicon-germanium layer with about 2 to about 5% germanium is used for the solar cell. Here, a silicon-germanium layer on top of a substrate such as glass may be crystallized as described above.

According to further aspects of the innovations herein, plastic or stainless steel base material may be used as the substrate. For example, the use of plastic substrates along with these innovations enables low cost flexible solar cells which can be integrated more easily with, e.g., buildings. One exemplary use of plastic substrates with the innovations herein includes integrating solar cells with windows of commercial buildings (also known as BIPV or Building-integrated-photovoltaics).

It is to be understood that the foregoing description is intended to illustrate and not to limit the scope of the inventions herein, which are defined by the scope of the claims. Other implementations are within the scope of the claims.

1. A method of producing a composite structure composed of a silicon-containing material bonded to a substrate, the method comprising:
implanting ions into silicon-containing material to a depth;
engaging the silicon-containing piece into contact with the substrate; and
irradiating/treating the silicon-containing piece with a laser having a wavelength of between about 350 nm to about 1070 nm.

2. The method of claim 1 wherein the substrate is a borosilicate/borofloat glass or a soda-lime glass.

3. The method of claim 1 further comprising cleaving the silicon-containing material along a surface established at about the depth at which the ions are implanted.

4. The method of claim 1 wherein the irradiation step is performed with a laser having a wavelength between about 500 nm and about 600 nm.

5. The method of claim 1 wherein the irradiation step is performed with a laser having a wavelength of about 515 nm or about 532 nm.

6. The method of claim 1 wherein the substrate includes a base portion composed of glass, plastic or metal.

7. The method of claim 1 wherein the substrate comprises one or more layers including a film of SiN/SiO2/Si coated on a base portion.

8. The method of claim 1 further comprising of a step of annealing at a temperature between about 200° C. to about 450° C.

9. The method of claim 1 further comprising of a step of annealing at a temperature between about 200° C. to about 450° C. for a period of less than about 45 minutes.

10. The method of claim 8 wherein the step of annealing is performed after a step of laser irradiation/treatment.

11. (canceled)

12. A method of producing a composite solar cell structure composed of a silicon-containing material bonded to a glass substrate, the method comprising:
engaging the silicon-containing piece into contact with the glass substrate; and
irradiating/treating the silicon-containing piece with a laser having a wavelength of between about 350 nm to about 1070 nm, such that complete bonding between the piece and the glass substrate is achieved without need for further anneal.

13. (canceled)

14. The method of claim 12 wherein the irradiation step is performed with a laser having a wavelength between about 500 nm and about 600 nm.

15-16. (canceled)

17. A method of producing a composite structure composed of a silicon-containing material bonded to a substrate, the method comprising:
implanting ions into silicon-containing material to a depth;
holding the silicon-containing piece into contact with the substrate;
irradiating/treating the silicon-containing piece with a laser having a wavelength of between about 350 nm to about 1070 nm; and
cleaving the silicon-containing material along a surface established at about the depth at which the ions are implanted.

18. (canceled)

19. The method of claim 17 further comprising cleaving the silicon-containing material along a surface established at the depth at which the ions are implanted.

20. The method of claim 17 wherein the irradiation step is performed with a laser having a wavelength between about 500 nm and about 600 nm.

21-27. (canceled)

28. The method of claim 17 wherein the step of irradiation comprises:
a first pass of the laser at an energy density of between about 0.5 and about 3 J/cm2; and
a second pass of the laser at an energy density of between about 0.5 and about 3 J/cm2.

29. (canceled)

30. The method of claim 17 wherein the step of irradiation comprises:
a first pass of the laser at an energy density of between about 0.5 and about 1 J/cm2;
a second pass of the laser at an energy density of between about 1 and about 1.5 J/cm2; and
a third pass of the laser at an energy density of between about 1.5 and about 3 J/cm2.

31. The method of claim 17 wherein the step of irradiation comprises:
a first pass of the laser at an energy density of between about 1.5 and about 3 J/cm2;
a second pass of the laser at an energy density of between about 1 and about 1.5 J/cm2; and
a third pass of the laser at an energy density of between about 0.5 and about 1 J/cm2.

32. The method of claim 17 wherein the step of irradiation comprises:
a first pass of the laser, at a speed/rate of about 0.0001 to about 0.01 cm2/sec, at an energy density of between about 0.5 and about 1 J/cm2; and
a second pass of the laser, at a speed/rate of about 0.01 to about 10 cm2/sec at an energy of between about 1 and about 3 J/cm2.

33. The method of claim 17 wherein the step of irradiation comprises:
a first pass of the laser, at a speed/rate of about 0.0001 to about 0.01 cm2/sec, at an energy density of between about 0.5 and about 1 J/cm2;
a second pass of the laser, at a speed/rate of about 0.01 to about 10 cm2/sec at an energy of between about 1 and about 2 J/cm2; and
a third pass of the laser, at a speed/rate of about 0.01 to about 10 cm2/sec at an energy of between about 2 and about 3 J/cm2.

34-38. (canceled)
